(19) United States
(12) Patent Application Publication
(10) Pub. No.: US 2020/0162024 A1
(43) Pub. Date: May 21, 2020

(54) PIEZORESISTIVE SELF-OSCILLATOR

(71) Applicant: Intel Corporation, Santa Clara, CA (US)

(72) Inventors: Dmitri E. Nikonov, Beaverton, OR (US); Raseong Kim, Portland, OR (US); Sasikanth Manipatruni, Portland, OR (US); Ian A. Young, Portland, OR (US); Gary Alfred Allen, Portland, OR (US); Tanay Gosavi, Hillsboro, OR (US)

(73) Assignee: Intel Corporation, Santa Clara, CA (US)

(21) Appl. No.: 16/192,841

(22) Filed: Nov. 16, 2018

(51) Int. Cl. H03B 5/24; H01L 29/78; H01L 27/06

(52) U.S. Cl. CPC H03B 5/24; H01L 29/42364; H01L 27/0629; H01L 29/785

(57) ABSTRACT

Embodiments may relate to a piezoresistive oscillator. The oscillator may include a fin field-effect transistor (FinFET) with a source electrode, a drain electrode, and a gate electrode. The oscillator may further include an electrical coupling coupled with the FinFET, wherein the electrical coupling electrically couples the gate electrode to the source electrode or the drain electrode. Other embodiments may be described or claimed.

### BACKGROUND

On-chip oscillators may be used for a variety of applications: clock generation, radio frequency (RF) transceivers, neuromorphic computing, etc. Many on-chip oscillators may be complementary metal-oxide-semiconductor (CMOS)-based oscillators. Examples of CMOS-based oscillators may include ring oscillators, self-biased oscillators, inductor-capacitor (LC) oscillators, etc. These CMOS oscillators may include tens or hundreds of transistors or have a large inductance. Because of the number of transistors and the size of the inductance, the CMOS oscillators may have a relatively large size or may consume significant system power.

### BRIEF DESCRIPTION OF THE DRAWINGS

FIG. 1 depicts a simplified diagram of an example fin field-effect transistor (FinFET), in accordance with embodiments herein.

FIG. 2 depicts an example diagram of a circuit that includes a FinFET, in accordance with embodiments herein.

FIG. 3 depicts an alternative example diagram of a circuit that includes a FinFET, in accordance with embodiments herein.

FIG. 4 depicts an alternative example diagram of a circuit that includes a FinFET, in accordance with embodiments herein.

FIG. 5 depicts an example small-signal model of the circuit of FIGS. 2 and 3, in accordance with various embodiments.

FIG. 6 depicts an example small-signal model of the circuit of FIG. 4, in accordance with various embodiments.

### DETAILED DESCRIPTION

In the following detailed description, reference is made to the accompanying drawings which form a part hereof, wherein like numerals designate like parts throughout, and in which is shown by way of illustration embodiments in which the subject matter of the present disclosure may be practiced. It is to be understood that other embodiments may be utilized and structural or logical changes may be made without departing from the scope of the present disclosure. Therefore, the following detailed description is not to be taken in a limiting sense, and the scope of embodiments is defined by the appended claims and their equivalents.

For the purposes of the present disclosure, the phrase “A or B” means (A), (B), or (A and B). For the purposes of the present disclosure, the phrase “A, B, or C” means (A), (B), (C), (A and B), (A and C), (B and C), or (A, B and C).

The description may use perspective-based descriptions such as top/bottom, in/out, over/under, and the like. Such descriptions are merely used to facilitate the discussion and are not intended to restrict the application of embodiments described herein to any particular orientation.

The description may use the phrases “in an embodiment,” or “in embodiments,” which may each refer to one or more of the same or different embodiments. Furthermore, the terms “comprising,” “including,” “having,” and the like, as used with respect to embodiments of the present disclosure, are synonymous.

The term “coupled with,” along with its derivatives, may be used herein. “Coupled” may mean one or more of the following. “Coupled” may mean that two or more elements are in direct physical or electrical contact. However, “coupled” may also mean that two or more elements indirectly contact each other, but yet still cooperate or interact with each other, and may mean that one or more other elements are coupled or connected between the elements that are said to be coupled with each other. The term “directly coupled” may mean that two or elements are in direct contact.

In various embodiments, the phrase “a first feature formed, deposited, or otherwise disposed on a second feature,” may mean that the first feature is formed, deposited, or disposed over the feature layer, and at least a part of the first feature may be in direct contact (e.g., direct physical or electrical contact) or indirect contact (e.g., having one or more other features between the first feature and the second feature) with at least a part of the second feature.

Various operations may be described as multiple discrete operations in turn, in a manner that is most helpful in understanding the claimed subject matter. However, the order of description should not be construed as to imply that these operations are necessarily order dependent.

Embodiments herein may be described with respect to various Figures. Unless explicitly stated, the dimensions of the Figures are intended to be simplified illustrative examples, rather than depictions of relative dimensions. For example, various lengths/widths/heights of elements in the Figures may not be drawn to scale unless indicated otherwise. Additionally, some schematic illustrations of example structures of various devices and assemblies described herein may be shown with precise right angles and straight lines, but it is to be understood that such schematic illustrations may not reflect real-life process limitations which may cause the features to not look so “ideal” when any of the structures described herein are examined, e.g., using scanning electron microscopy (SEM) images or transmission electron microscope (TEM) images. In such images of real structures, possible processing defects could also be visible, e.g., not-perfectly straight edges of materials, tapered vias or other openings, inadvertent rounding of corners or variations in thicknesses of different material layers, occasional screw, edge, or combination dislocations within the crystalline region, and/or occasional dislocation defects of single atoms or clusters of atoms. There may be other defects not listed here but that are common within the field of device fabrication.

As noted above, CMOS-based oscillators may have a relatively large size or require a relatively high amount of system power. Because of that, various other oscillators may be considered for use in the above-described application. These oscillators may be smaller or consume less power. These oscillators may include, for example, spin torque oscillators, metal-insulator transition (MIT) oscillators, or piezoresistive oscillators. However, these oscillators may have one or more undesirable characteristics in certain use-cases. For example, piezoresistive devices may include separate electric-to-strain (“drive”) and strain-to-electric (“sense”) transduction modules, and therefore may not have sufficient gain to produce amplification. Therefore, these piezoresistive devices may, in many situations, act more like resonator devices rather than oscillator devices. More specifically, these piezoresistive devices may not produce a self-sustained oscillation due to their relatively low gain.

By contrast, embodiments herein may relate to use of a single FinFET as a “drive” and “sense” transducer. More specifically, the drain and the gate or the source and the gate of the FinFET may be connected to one another. The connection may be, in some embodiments, dependent on the sign of the piezoresistive coefficient to obtain the loop gain. For example, in some embodiments the gate may be coupled to the drain or the source of the FinFET based on whether the sign of the piezoresistive coefficient is positive or negative.

This embodiment based on the piezoresistive (PzR) effect in the FinFET, and particularly the discussed coupling of the gate to the drain or source, may provide a number of advantages compared to traditional CMOS oscillators. First, an oscillator that uses PzR effect may be more compact, for example only comprising two transistors, compared to tens or sometimes hundreds of transistors. Secondly, PzR effect may provide an oscillator based on a FinFET that undergoes self-sustained oscillation, compared to other piezoresistive device-based circuits which only have a resonance. Finally, the oscillator may only require relatively low power for operation. In some embodiments, the power level may be determined based on the product of the supply voltage and the on-current of one fin of the FinFET.

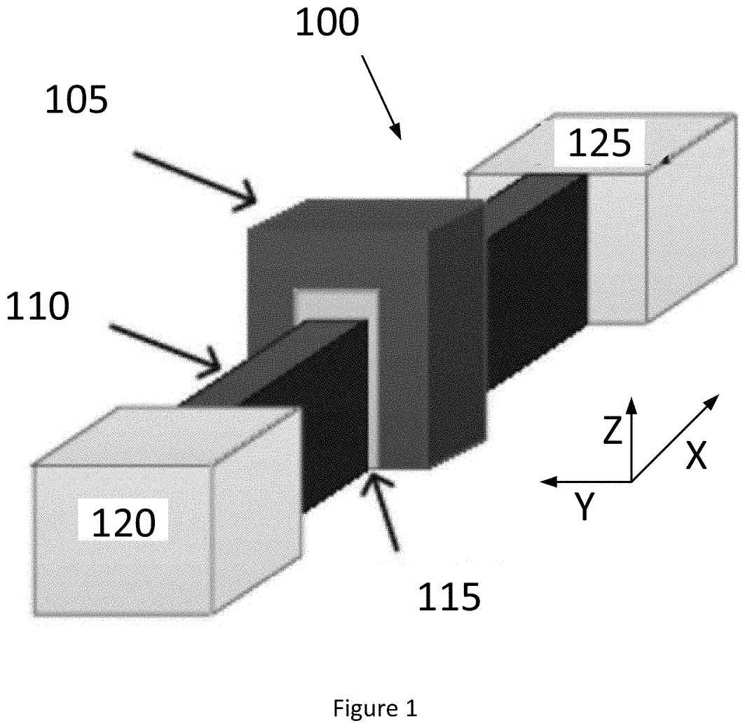

FIG. 1 depicts a simplified diagram of an example FinFET 100, in accordance with embodiments herein. The FinFET 100 may include a metal gate 105, which may be composed of a metal with an appropriate work function, e.g. copper (Cu), titanium (Ti), nickel (Ni), hafnium (Hf), iridium (Ir), or gold (Au). The FinFET 100 may additionally include a source portion 120 and a drain portion 125. The source portion 120 and the drain portion 125 may be connected by a fin 110. In embodiments, the source portion 120 or the drain portion 125 may be composed of a semiconducting material, e.g. silicon (Si), germanium (Ge), SiGe. The fin 110 may be composed of another semiconducting material, e.g. Si, Ge, SiGe. In some embodiments a gate dielectric material 115 may be placed between the fin 110 and the metal gate 105. The gate dielectric material 115 may be, for example, an oxide material or some other dielectric material.

As can be seen in FIG. 1, in embodiments the metal gate 105 may generally surround the fin 110 on at least two sides of the fin 110. For example, in FIG. 1 the metal gate 105 may be said to surround the fin 110 on three sides of the fin 110 (the top side, the left side, and the right side of the fin 110 as generally oriented in FIG. 1). Generally, the FinFET 100 may have smaller dimensions than a legacy CMOS oscillator. For example, the FinFET 100 may have a dimension along the Z-axis (e.g., a “height”) of approximately 30 nanometers (nm). The FinFET 100 may have a dimension along the Y-axis (e.g., a “width”) of approximately 40 nm. The FinFET 100 may have a dimension along the X-axis (e.g., a “length”) of approximately 100 nm. It will be understood that these dimensions are intended only as examples and in other embodiments the FinFET 100 may have different dimensions along one or more of the listed axes. Such variations may be based on, for example, specific desired properties of the FinFET, the materials used, the design considerations of a device in which the FinFET will be used, or other considerations.

It will be understood that the depiction of the FinFET 100 in FIG. 1 is intended as an example of a FinFET, and various embodiments may have alternative characteristics. For example, even though the various elements such as the fin 110, the metal gate 105, the source portion 120, the drain portion 125, or the gate dielectric material 115 are depicted as having a generally rectangular or square cross-section, in other embodiments one or more of the various elements may have a different cross-section such as circular, triangular, trapezoidal, etc. Additionally, various measurements of the elements are generally depicted in FIG. 1 as being constant (e.g., the fin 110 has a constant width, in other embodiments the width, length, or height of one or more of the elements may vary along one or more of the axes. For example, the width of the fin 110 may change across the length of the fin 110. Additionally, it will be understood as previously noted that the FinFET 100 of FIG. 1 is intended as a simplified example of a FinFET. Other FinFETs may have additional elements (e.g., additional fins or additional gates), or may include one or more additional elements coupled to one or more of the fin 110, the metal gate 105, the source portion 120, the drain portion 125, or the gate dielectric material 115. For example, in some embodiments one or more of the metal gate 105, source portion 120, or drain portion 125 may be coupled with a voltage input, an electrode, an additional circuit element such as a resistor/capacitor/transistor/etc., or some other element. In some embodiments, the FinFET 100 may be coupled with another element of a computing or electronic device such as a substrate, an interposer, an overmold material, a processor, a memory, etc.

As noted above, in embodiments the metal gate 105 may be electrically coupled with either the source portion 120 or the drain portion 125. This coupling may provide an oscillator that is based on the electrostatic force which may be created by charges on the metal gate 105 of the FinFET 100, and the resultant strain exerted on the fin 110. The resistance of the fin 110 may then change due to the strain, which may result in a piezoresistive oscillating effect.

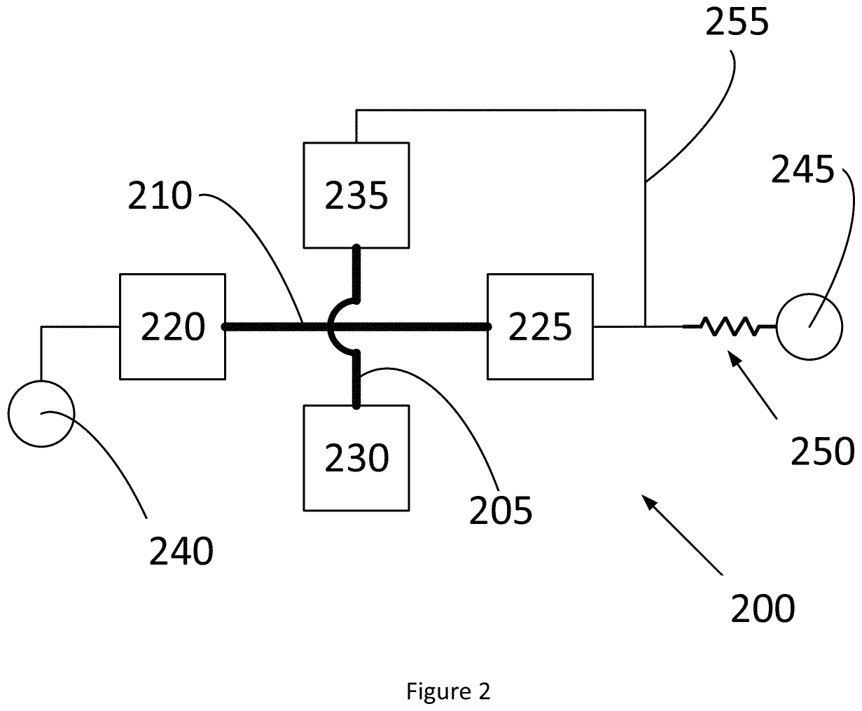

FIG. 2 depicts an example diagram of a circuit that includes a FinFET 200, in accordance with embodiments herein. The FinFET 200 may include a source portion 220, a drain portion 225, a metal gate 205, and a fin 210 which may be respectively similar to source portion 120, drain portion 125, metal gate 105, and fin 110. The metal gate 205 may be coupled with a gate electrode 235 and a gate electrode 230.

In some embodiments, the gate electrodes 235/230 may be elements of the metal gate 205, or in other embodiments they may be separate elements such as conductive pads that are coupled with the metal gate 205. Specifically, in some embodiments a wire or some other component of a system may be physically and communicatively coupled directly with the metal gate 205. In this embodiment, the gate electrodes 235/230 may be considered to be the portion of the metal gate 205 to which the wire is coupled. In other embodiments, the gate electrodes 235/230 may be separate elements such as metal pads or some other conductive element that is communicatively coupled with the metal gate 205. In this embodiment, the wire may be physically coupled with the gate electrodes 235/230, and thereby communicatively coupled with the metal gate 205. However, for ease of discussion and explanation of the general connections and circuit elements of FIGS. 2-4, the gate electrodes 235/230 are depicted as distinct elements.

In some embodiments, a supply voltage can be provided to the FinFET 200 through electrode 245. Specifically, the FinFET 200 may include an electrode 245 which may be electrically coupled with the supply voltage. The supply voltage may be, for example, a battery, an active power source, or some other type of voltage source. The FinFET 200 may include an additional electrode 240 which may be coupled with ground. The electrode 240 may be electrically coupled with electrode 220 as depicted in FIG. 2.

The gate electrode 235 and the drain portion 225 of the FinFET 200 may be electrically coupled by an electrical coupling 255. The electrical coupling 255 may be, for example, made up of a conductive wire, a via, or some other electrical element. The electrical coupling 255 may be configured to allow the gate electrode 235 and the drain portion 225 to electrically communicate with one another. The drain portion 225 and the electrical coupling may further be coupled with a load resistance 250 that is electrically positioned between the drain portion 225 and an electrode 245 of the circuit of which the FinFET 200 is a part. The load resistance 250, as shown in FIG. 2, may be a resistor. In embodiments, the resistor may be a fixed resistor or a variable resistor. Additionally, although the load resistance 250 is depicted as a single resistor, in other embodiments the load resistance 250 may be a plurality of resistors or resistive elements, configured either in series or in parallel, as described in further detail below.

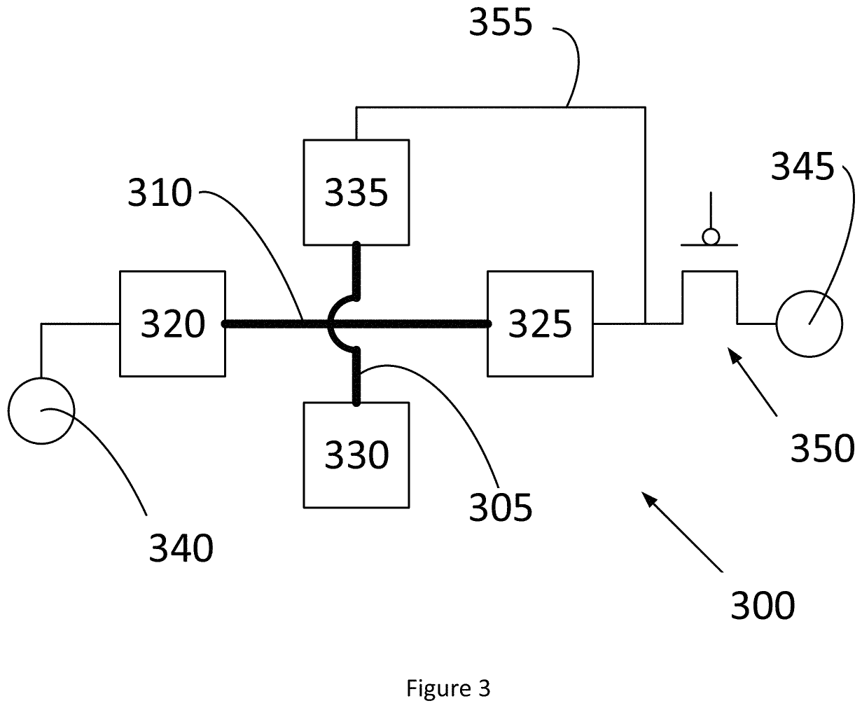

FIG. 3 depicts an alternative example diagram of a circuit that includes a FinFET 300, in accordance with embodiments herein. The FinFET 300 may include a fin 310, a source portion 320, a drain portion 325, a metal gate 305, a gate electrode 335, a gate electrode 330, an electrode 345, and a ground voltage electrode 340, which may be respectively similar to fin 210, source portion 220, drain portion 225, metal gate 205, gate electrode 235, gate electrode 230, electrode 245, and electrode 240. The circuit of which the FinFET 300 is a part may include an electrical coupling 355, which may be similar to electrical coupling 255. The circuit may further include a load resistance 350. As can be seen in FIG. 3, in embodiments the load resistance 350 may be a transistor with a fixed gate bias. Herein, the fixed gate bias may be referred to as “VB”.

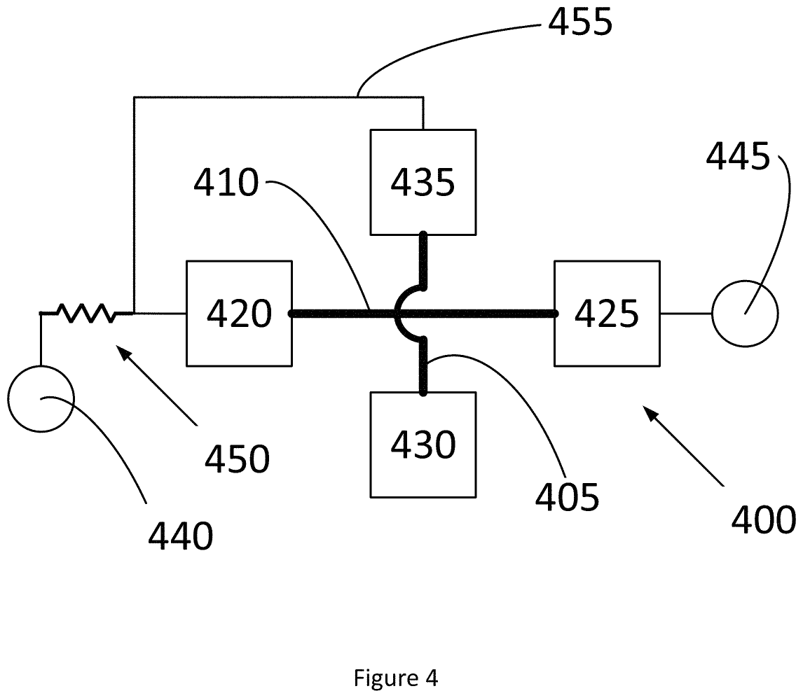

FIG. 4 depicts an alternative example diagram of a circuit that includes a FinFET 400, in accordance with embodiments herein. The FinFET 400 may include a fin 410, a source portion 420, a drain portion 425, a metal gate 405, a gate electrode 435, and a gate electrode 430, which may be respectively similar to fin 210, source portion 220, drain portion 225, metal gate 205, gate electrode 235, and gate electrode 230. The circuit of which the FinFET 400 is a part may include a load resistance 450 which may be similar to load resistance 250. It will be understood that in other embodiments, not depicted here for the sake of elimination of redundancy, the load resistance 450 may be similar to the load resistance 350. More specifically, even though the load resistance 450 is depicted as a resistor in FIG. 4, in other embodiments the load resistance 450 may be a fixed gate bias transistor such as is depicted in FIG. 3 with respect to load resistance 350.

The circuit may further include an electrical coupling 455, an electrode 445, and a ground voltage electrode 440, which may be respectively similar to electrical coupling 255, electrode 245, and electrode 240. However, as can be seen in FIG. 4, the electrode 445 may not be electrically coupled with the gate electrode 435 by electrical coupling 455. Rather, the electrode 440 may be electrically coupled with the gate electrode 435 by the electrical coupling 455, as well as the source portion 420. Additionally, rather than the load resistance 450 being electrically positioned between the drain portion 425 and the electrode 445, the load resistance 450 may be electrically positioned between the electrode 440 and the source portion 420 as depicted in FIG. 4

In other embodiments the resistor used for the load resistances 250/450 or the transistor used for the load resistance 350 may be replaced by a different type of resistance in other circuits. In some embodiments, the load resistance 250/350/450 may be a plurality of resistive elements such as a plurality of resistors, a plurality of transistors, a plurality of other resistive elements, or some combination thereof. These elements may be arranged in series or in parallel with one another. The function of the load resistance 250 and 350 is discussed below.

In general, the circuit depicted in FIGS. 2 and 3 (e.g., the circuit wherein the gate input is electrically coupled with the drain portion of the FinFET), as will be described in further detail below, may enable self-sustaining oscillation of the fin 210/310 in cases where the material used for the fin has a relative change of channel conductance per unit tensile/compressive strain greater/less than 0 (i.e., Pᵣ>0 or equivalently Π<0 in Tables I and II, conductance increasing/decreasing (resistance decreasing/increasing) with tensile/compressive strain). Such a material may be, for example, n-doped silicon with crystal orientation of x=[110], y=[−110]. By contrast, the circuit depicted in FIG. 4 (e.g., the circuit wherein the gate input is electrically coupled with the source portion of the FinFET), as will be described in further detail below, may enable self-sustaining oscillation of the fin 410 in cases where the material used for the fin has a relative change of channel conductance per unit tensile/compressive strain of less/greater than 0 (i.e., Pᵣ<0 or equivalently Π>0 in Tables I and II, conductance decreasing/increasing (resistance increasing/decreasing) with tensile/compressive strain). Such a material may be, for example, n-doped silicon with crystal orientation of x=[110], y=[001], or some other material discussed in Table II.

It will also be recognized that the circuits depicted in FIGS. 2, 3, and 4 are intended as simplified diagrams. Other embodiments of the circuits of FIG. 2, 3, or 4 may include additional elements that are not depicted in FIG. 2, 3, or 4 such as additional resistors, transistors, capacitors, power amplifiers, etc.

The operation of a circuit such as the circuit depicted in FIG. 2 or 3 may be described by the following equations. A phenomenological equation for forced elastic vibrations may be:

$$\frac{{d}^{2} ɛ}{{dt}^{2}} + \frac{{ω}_{p}}{Q} \frac{d ɛ}{d t} + {ω}_{p}^{2} ɛ = {P}_{s} {v}_{in} , \qquad ( 1 )$$

where ε, ωₚ, [symbol] , and vᵢₙ may be the oscillating strain, resonant frequency (cyclic), quality factor of the resonator, and the voltage input at the gate, respectively. (Further details of the various parameters of equation 1 and other equations discussed herein may be depicted in greater detail in Table I, below). For parallel-plate actuation, the piezostrictive coefficient (Pₛ) may be:

$${P}_{s} = \frac{4 {c}_{g}^{2} {V}_{s} {ω}_{p}^{2}}{π {k}_{diel} {ɛ}_{0} Y} , \qquad ( 2 )$$

where c_{g}, Vₛ, k_{diel}, ε₀, and Y may be the gate capacitance, steady-state voltage at the central node, gate dielectric constant, vacuum permittivity, and Young's modulus, respectively.

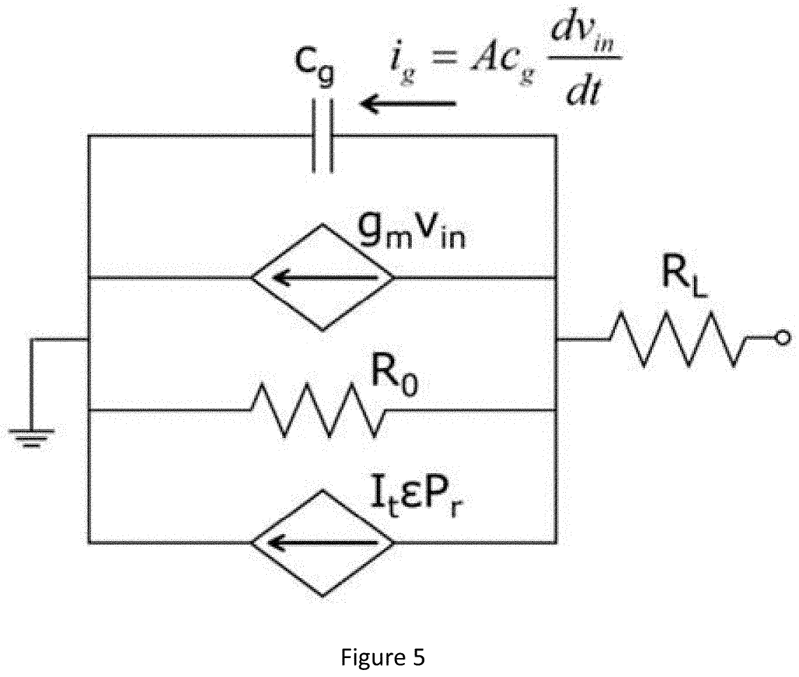

Using the equivalent small-signal circuit model of the circuit depicted in FIG. 2 or 3, an example of which may be depicted in FIG. 5, the small-signal current equation may be:

$${Ac}_{g} \frac{{dv}_{in}}{dt} = - {R}_{L \vert \vert 0}^{- 1} {v}_{out} - {g}_{m} {v}_{m} - {I}_{t} ɛ {P}_{r} , \qquad ( 3 )$$

where A, R₀, gₘ, Iₜ, and Pᵣ may be the total gate area, Early resistance, FinFET transconductance, static current of the transistor, and the relative change of current due to a unit tensile strain, respectively. Note that the variable Pᵣ as used in equation (3) may be related to the conventional piezoresistive (PZ) coefficient (Π) as Pᵣ=−ΠY, where the sign of H depends on the material, carrier type, and crystal orientations of the fin of the FinFET. Further details of these materials may be discussed below in Table II. Descriptions of embodiments herein may be given with respect to transverse PZ coefficients (Πₜ), because the direction of current flow through the fin 210 (e.g. along the X-axis in FIG. 1) may be approximately perpendicular to the strain direction of the fin 210 (e.g., along the Y-axis in FIG. 1).

In FIG. 2 or 3, the drain portion 225/325 and metal gate 205/305 may be shorted as vᵢₙ=vₒᵤₜ=v, in out, so the current equation may be:

$$\frac{dv}{dt} = - \frac{v}{τ} - \frac{{I}_{t} ɛ {P}_{r}}{{Ac}_{g}} , \qquad ( 4 )$$

where the circuit relaxation time may be:

$$τ = \frac{{Ac}_{g}}{{g}_{eff}} , \qquad ( 5 )$$

and the effective conductance of the transistor at given voltage may be:

g_{eff}=R_{L∥0}⁻¹+gₘ. (6)

From equation (1), the transfer function of the oscillator may be given as:

$$\frac{ɛ}{v} = S ( j ω ) = \frac{{P}_{s}}{{ω}_{p}^{2} - {ω}^{2} + j {ωω}_{p} \text{/} } . \qquad ( 7 )$$

From Eq. (4), the transfer function for the electric circuit such as the circuit depicted in FIG. 2 or 3 may be given as:

$$\frac{v}{ɛ} = C ( j ω ) = \frac{- {I}_{t} {P}_{r}}{{g}_{eff} ( 1 + j ωτ )} , \qquad ( 8 )$$

where the oscillating frequency may be ω. Then the loop gain may be:

LG(jω)=S(jω)C(jω) (9)

One condition for the onset of oscillations may be that the loop gain is greater or equal to 1, and the phase equal to 0 as:

Re[LG(jω)]>1 (10a)

Im[LG(jω)]=0 (10b)

Eq. (10b) may result in the condition for the oscillating frequency ω:

$${ω}^{2} - {ω}_{p}^{2} = \frac{{ω}_{p}}{ τ} , \qquad ( 11 )$$

and Eq. (10a) may result in:

$$\frac{ τ}{{g}_{eff} {ω}_{p}} {I}_{t} {P}_{r} {P}_{s} - {ω}_{p}^{2} {τ}^{2} - \frac{{ω}_{p} τ}{} > 1. \qquad ( 12 )$$

The condition in Eq. (12) may be satisfied using material and circuit parameters such as those described in Table I, below, when Pᵣ>0 (e.g., current increases with tensile strain), or equivalently, Π<0 (e.g., resistance decreases with tensile strain). As an example, for a silicon (Si) negative-channel metal-oxide-semiconductor (nMOS) with x=[110] (channel direction in FIG. 1), y=[−110] (gate (or fin surface) direction in FIG. 1), and parameters such as those described below in Table I, the equations may obtain:

$$\frac{ τ}{{g}_{eff} {ω}_{p}} {I}_{t} {P}_{r} {P}_{s} - {ω}_{p}^{2} {τ}^{2} - \frac{{ω}_{p} τ}{} ∼ 7 > 1. \qquad ( 13 )$$

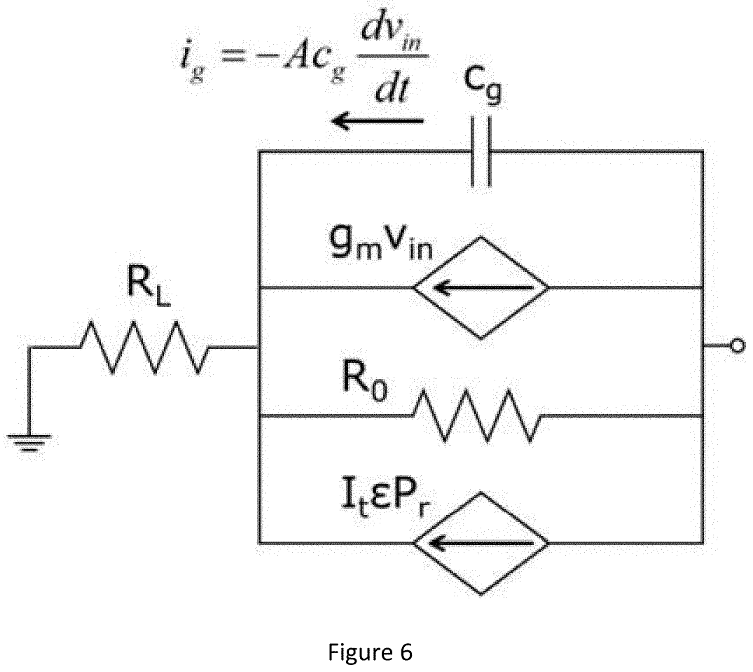

Alternatively, for cases with Pᵣ<0 (Π>0), the circuit configuration in FIG. 4 may be used to enable oscillation. Here the metal gate 405 of the FinFET 400 may be connected to its source portion 420. Note that the load resistance in FIG. 4 may be realized using a transistor (such as the transistor depicted in FIG. 3 as the load resistance 350), of which the type is complementary to the resonating FinFET 400. Using the equivalent small-signal circuit model to the circuit depicted in FIG. 4, an example of which may be depicted in FIG. 6, the small-signal current equation may be expressed as:

$${Ac}_{g} \frac{{dv}_{in}}{dt} = - {R}_{L □ 0}^{- 1} {v}_{out} + {g}_{m} {v}_{in} + {I}_{t} ɛ {P}_{r} . \qquad ( 14 )$$

In FIG. 4, the source portion 420 and the metal gate 405 may be shorted as vᵢₙ=vₒᵤₜ=v, so the current equation may be:

$$\frac{dv}{dt} = \frac{v}{τ} + \frac{{I}_{t} ɛ {P}_{r}}{τ {g}_{eff}} , \qquad ( 15 )$$

where the effective conductance of the transistor at given voltage may be:

g_{eff}=−R_{LD0}⁻¹+gₘ, (16)

and τ may be given by equation (5). The transfer function of the oscillator may still be given by equation (7), while the transfer function for the electric circuit of FIG. 4 may be given from equation (14) as:

$$\frac{v}{ɛ} = C ( j ω ) = \frac{- {I}_{t} {P}_{r}}{{g}_{eff} ( 1 - j ωτ )} . \qquad ( 17 )$$

Then the condition of the onset of oscillation in equation (10b) may be:

$${ω}_{p}^{2} - {ω}^{2} = \frac{{ω}_{p}}{ τ} , \qquad ( 18 )$$

and the condition in equation (10a) may be:

$$- \frac{ τ}{{g}_{eff} {ω}_{p}} {I}_{t} {P}_{r} {P}_{s} - {ω}_{p}^{2} {τ}^{2} + \frac{{ω}_{p} τ}{} > 1. \qquad ( 19 )$$

The condition in equation (19) may be satisfied using material and circuit parameters such as those discussed below in Table I when Pᵣ<0 (current decreases with tensile strain), or equivalently, Π>0 (resistance increases with tensile strain). As an example, for an Si nMOS with x=[110] (channel direction in FIG. 1), y=[001] (gate (or fin surface) direction in FIG. 1), and parameters such as those discussed below in Table I, the equations may result in:

$$- \frac{ τ}{{g}_{eff} {ω}_{p}} {I}_{t} {P}_{r} {P}_{s} - {ω}_{p}^{2} {τ}^{2} + \frac{{ω}_{p} τ}{} ∼ 22 > 1. \qquad ( 20 )$$

Table I, below, depicts example material and device parameters. Note that some parameters may be shown in Table I for two different cases. Case A may relate to circuits such as those depicted in FIG. 2, 3, or 5. E.g., circuits wherein Pᵣ may be greater than 0. Case B may relate to circuits such as those depicted in FIG. 4 or 6, e.g. circuits wherein Pᵣ may be less than 0. It will be understood that the list of parameters depicted below in Table I are intended as example parameters. Some parameters of the equations above may not be listed in Table I, as they may already be known to an ordinarily skilled artesian.

TABLE I
Example Material and Device Parameters

| Quantity | Symbol | Value | Units |
|---|---|---|---|
| Q-factor of the piezo resonator | Q | 10000 | |
| piezo resonant frequency, cyclic | ωₚ | 2π*50 | Gigaradians per |
| | | | second (G * rad/s) |
| Young's modulus of Si | Y | 170 (case A) | Gigapascals (GPa) |
| | | (Si, x = [110], y = [−110]) | |
| | | 130 (case B) | |
| | | (Si, x = [110], y = [001]) | |
| transverse piezoresistive | Πₜ | −1.76 * 10⁻¹⁰ (case A) | Meters |
| coefficient | | (Si nMOS, x = [110], | squared per |
| | | y = [−110]) | Newton |
| | | +5.34 * 10⁻¹⁰ (case B) | (m²/N) |
| | | (Si nMOS, x = [110], | |
| | | y = [001]) | |
| relative change of the channel | Pᵣ | 30 (case A) | |
| resistance per unit strain | | −69 (case B) | |
| gate dielectric thickness | tₒₓ | 2 | Nanometers (nm) |
| gate dielectric constant | k_{diel} | 20 | |
| gate capacitance per unit area | c_{g} | 0.09 | Farads per |
| | | | square meter (F/m²) |
| gate area | A | 2000 | Square |
| | | | nanometers (nm²) |
| Early resistance | R₀ | 50 | Kiloohms (kΩ) |
| linear transconductance of the | gₘ | 0.1 | Millisiemens |
| transistor | | | (mS) |
| current through the transistor | Iₜ | 0.05 | Milliamps (mA) |
| steady-state voltage at the central | Vₛ | 0.5 (case A) | Volts (V) |
| node | | 0.1 (case B) | |
| load resistance | R_{L} | 50 | kΩ |
| effective transconductance | g_{eff} | 0.14 (case A) | mS |
| | | 0.06 (case B) | |
| circuit relaxation time | τ | 1.3 (case A) | Picoseconds |
| | | 3.0 (case B) | (ps) |
| piezostrictive coefficient | Pₛ | 1.6 * 10¹⁹ (case A) | Per volt per square |
| | | 4.3 * 10¹⁸ (case B) | second (1/V/s²) |

Table II, below, depicts example PZ coefficients (Πₜ in units of m²/N) for different materials such as Si or germanium (Ge), carrier type, and crystal orientations.

TABLE II
Example PZ coefficients

| material | carrier type | x/y = [110]/[−110] | x/y = [110]/[001] |
|---|---|---|---|
| Si | n-type | −1.76 * 10⁻¹⁰ | 5.34 * 10⁻¹⁰ |
| | p-type | −6.63 * 10⁻¹⁰ | −1.1 * 10⁻¹¹ |
| Ge | n-type | 6.4 * 10⁻¹⁰ | −5.5 * 10⁻¹¹ |
| | p-type | −4.15 * 10⁻¹⁰ | 5.0 * 10⁻¹¹ |

### EXAMPLES OF VARIOUS EMBODIMENTS

Example 1 includes a piezoresistive oscillator comprising: a fin field-effect transistor (FinFET) that includes a source electrode, a drain electrode, and a gate electrode; and an electrical coupling coupled with the FinFET, wherein the electrical coupling electrically couples the gate electrode to the source electrode or the drain electrode.

Example 2 includes the piezoresistive oscillator of example 1, wherein the gate electrode is coupled with an input voltage of the piezoresistive oscillator.

Example 3 includes the piezoresistive oscillator of example 1, wherein the FinFET includes: a channel that physically and electrically couples the source electrode and the drain electrode; and a gate portion that is physically and electrically coupled to the gate electrode, wherein the gate portion is physically coupled to the channel on at least two sides of the channel.

Example 4 includes the piezoresistive oscillator of example 1, further comprising a load resistance electrically coupled with the electrical coupling.

Example 5 includes the piezoresistive oscillator of example 4, wherein the load resistance is a resistor or a transistor with a fixed gate bias.

Example 6 includes the piezoresistive oscillator of any of examples 1-5, wherein the electrical coupling is to electrically couple the gate electrode to the source electrode or the drain electrode based on whether a change of conductance of the channel per unit tensile strain (Pᵣ) is positive or negative.

Example 7 includes the piezoresistive oscillator of example 6, wherein the electrical coupling electrically couples the gate electrode to the source electrode if Pᵣ is negative.

Example 8 includes the piezoresistive oscillator of example 6, wherein the electrical coupling electrically couples the gate electrode to the drain electrode if Pᵣ is positive.

Example 9 includes a circuit comprising: a voltage source; a transistor coupled with the voltage source, wherein the transistor includes: a source electrode, a drain electrode, and a fin that electrically and physically couples the source electrode to the drain electrode; and a first gate electrode, a second gate electrode, and a fin that electrically and physically couples the first gate electrode to the second gate electrode, wherein the gate portion is physically coupled with the fin on at least two sides of the fin; and an electrical coupling that electrically couples the first gate electrode to the source electrode or the drain electrode.

Example 10 includes the circuit of example 9, further comprising a load resistance electrically coupled with the electrical coupling.

Example 11 includes the circuit of example 10, wherein the load resistance is a resistor.

Example 12 includes the circuit of example 10, wherein the load resistance is a transistor with a fixed gate bias.

Example 13 includes the circuit of any of examples 9-12, wherein the electrical coupling is to electrically couple the first gate electrode to the source electrode or the drain electrode based on a change of conductance of the fin per unit tensile strain (Pᵣ).

Example 14 includes the circuit of example 13, wherein the electrical coupling electrically couples the first gate electrode the source electrode if Pᵣ is negative.

Example 15 includes the circuit of example 13, wherein the electrical coupling electrically couples the first gate electrode the drain electrode if Pᵣ is positive.

Example 16 includes a circuit comprising: a fin field-effect transistor (FinFET) with a source electrode, a drain electrode, a first gate electrode, and a second gate electrode, wherein the first gate electrode is coupled with one of the source electrode and the drain electrode; and a load resistance electrically coupled with the first gate electrode and the one of the source electrode and the drain electrode.

Example 17 includes the circuit of example 16, wherein the load resistance is a resistor or a transistor with a fixed gate bias.

Example 18 includes the circuit of example 16, wherein the first gate electrode is to be electrically coupled with the one of the source electrode or the drain electrode based on a change of conductance of the fin per unit tensile strain (Pᵣ).

Example 19 includes the circuit of any of examples 16-18, further comprising a fin physically and electrically coupled with the source electrode and the drain electrode, and wherein the fin is to oscillate when voltage is applied to the FinFET.

Example 20 includes the circuit of example 19, wherein the degree of oscillation is based on the voltage and the load resistance.

Various embodiments may include any suitable combination of the above-described embodiments including alternative (or) embodiments of embodiments that are described in conjunctive form (and) above (e.g., the “and” may be “and/or”). Furthermore, some embodiments may include one or more articles of manufacture (e.g., non-transitory computer-readable media) having instructions, stored thereon, that when executed result in actions of any of the above-described embodiments. Moreover, some embodiments may include apparatuses or systems having any suitable means for carrying out the various operations of the above-described embodiments.

The above description of illustrated embodiments, including what is described in the Abstract, is not intended to be exhaustive or limiting as to the precise forms disclosed. While specific implementations of, and examples for, various embodiments or concepts are described herein for illustrative purposes, various equivalent modifications may be possible, as those skilled in the relevant art will recognize. These modifications may be made in light of the above detailed description, the Abstract, the Figures, or the claims.

1. A piezoresistive oscillator comprising:
a fin field-effect transistor (FinFET) that includes a source electrode, a drain electrode, and a gate electrode; and
an electrical coupling coupled with the FinFET, wherein the electrical coupling electrically couples the gate electrode to the source electrode or the drain electrode.

2. The piezoresistive oscillator of claim 1, wherein the gate electrode is coupled with an input voltage of the piezoresistive oscillator.

3. The piezoresistive oscillator of claim 1, wherein the FinFET includes:
a channel that physically and electrically couples the source electrode and the drain electrode; and
a gate portion that is physically and electrically coupled to the gate electrode, wherein the gate portion is physically coupled to the channel on at least two sides of the channel.

4. The piezoresistive oscillator of claim 1, further comprising a load resistance electrically coupled with the electrical coupling.

5. The piezoresistive oscillator of claim 4, wherein the load resistance is a resistor or a transistor with a fixed gate bias.

6. The piezoresistive oscillator of claim 1, wherein the electrical coupling is to electrically couple the gate electrode to the source electrode or the drain electrode based on whether a change of conductance of the channel per unit tensile strain (Pᵣ) is positive or negative.

7. The piezoresistive oscillator of claim 6, wherein the electrical coupling electrically couples the gate electrode to the source electrode if Pᵣ is negative.

8. The piezoresistive oscillator of claim 6, wherein the electrical coupling electrically couples the gate electrode to the drain electrode if Pᵣ is positive.

9. A circuit comprising:
a voltage source;
a transistor coupled with the voltage source, wherein the transistor includes:
a source electrode, a drain electrode, and a fin that electrically and physically couples the source electrode to the drain electrode; and
a first gate electrode, a second gate electrode, and a fin that electrically and physically couples the first gate electrode to the second gate electrode, wherein the gate portion is physically coupled with the fin on at least two sides of the fin; and
an electrical coupling that electrically couples the first gate electrode to the source electrode or the drain electrode.

10. The circuit of claim 9, further comprising a load resistance electrically coupled with the electrical coupling.

11. The circuit of claim 10, wherein the load resistance is a resistor.

12. The circuit of claim 10, wherein the load resistance is a transistor with a fixed gate bias.

13. The circuit of claim 9, wherein the electrical coupling is to electrically couple the first gate electrode to the source electrode or the drain electrode based on a change of conductance of the fin per unit tensile strain (Pᵣ).

14. The circuit of claim 13, wherein the electrical coupling electrically couples the first gate electrode the source electrode if Pᵣ is negative.

15. The circuit of claim 13, wherein the electrical coupling electrically couples the first gate electrode the drain electrode if Pᵣ is positive.

16. A circuit comprising:
a fin field-effect transistor (FinFET) with a source electrode, a drain electrode, a first gate electrode, and a second gate electrode, wherein the first gate electrode is coupled with one of the source electrode and the drain electrode; and
a load resistance electrically coupled with the first gate electrode and the one of the source electrode and the drain electrode.

17. The circuit of claim 16, wherein the load resistance is a resistor or a transistor with a fixed gate bias.

18. The circuit of claim 16, wherein the first gate electrode is to be electrically coupled with the one of the source electrode or the drain electrode based on a change of conductance of the fin per unit tensile strain (Pᵣ).

19. The circuit of claim 16, further comprising a fin physically and electrically coupled with the source electrode and the drain electrode, and wherein the fin is to oscillate when voltage is applied to the FinFET.

20. The circuit of claim 19, wherein the degree of oscillation is based on the voltage and the load resistance.
